(19) United States
(12) Patent Application Publication
(10) Pub. No.: US 2024/0387092 A1
(43) Pub. Date: Nov. 21, 2024

(54) INDUCTIVE DEVICE

(71) Applicant: QUALCOMM Incorporated, San Diego, CA (US)

(72) Inventors: Kai LIU, Phoenix, AZ (US); Jui-Yi CHIU, Taichung City (TW); Jonghae KIM, San Diego, CA (US); Nosun PARK, San Diego, CA (US); Je-Hsiung LAN, San Diego, CA (US)

(21) Appl. No.: 18/317,366

(22) Filed: May 15, 2023

(51) Int. Cl. H01F 17/00; H01F 27/02; H01F 27/06; H01F 27/255; H01F 27/28; H01F 27/29

(52) U.S. Cl. CPC H01F 17/0013; H01F 27/022; H01F 27/06; H01F 27/255; H01F 27/2828; H01F 27/292

(57) ABSTRACT

An inductive device includes multiple packaged devices, each including a body and a conductor layer within the body and a set of external connectors. The conductor layer of a packaged device includes a set of conductive lines electrically connected to the set of external connectors of the packaged device. Conductive lines of two packaged devices of the inductive device are at an angle relative to one another. External connectors of the packaged devices are coupled to one another to electrically connect the sets of conductive lines to define one or more coils, each coil having multiple turns and each turn including a conductive line of each packaged device.

### FIELD

Various features relate to inductive devices.

### BACKGROUND

Integrated circuit (IC) technology has achieved great strides in advancing computing power through miniaturization of active components. Integrated passive components have also been miniaturized, and the trend for further miniaturization of such components continues. Passive inductive elements are often some of the larger elements in a circuit in part because characteristic electrical properties of an inductive element are related to physical dimensions of the inductive element. For example, inductance of the inductive element is related to an aperture of a coil of the inductive element, and current carrying capacity of the inductive element is related to dimensions of conductive elements of the coil. Due to these and other factors, there is a need for high current, high inductance inductive devices that have a small form factor.

### SUMMARY

Various features relate to inductive devices.

One example provides an inductive device that includes a first packaged device and a second packaged device. The first packaged device includes a first body and a first conductor layer at least partially enclosed within the first body. The first conductor layer includes a first set of conductive lines extending along a first direction and offset from one another in a second direction. The first packaged device also includes a first set of external connectors electrically connected to the first conductor layer and extending along a third direction, through openings in the first body, to a face of the first body. The second packaged device includes a second body and a second conductor layer at least partially enclosed within the second body. The second conductor layer includes a second set of conductive lines offset from one another in the second direction and extending along a fourth direction that is angularly offset from the first direction. The second packaged device also includes a second set of external connectors electrically connected to the second conductor layer and extending along the third direction, through openings in the second body, to a face of the second body. The first set of external connectors is coupled to the second set of external connectors to electrically connect the first set of conductive lines to the second set of conductive lines to define a coil having multiple turns, where each turn includes a conductive line of the first set of conductive lines and a conductive line of the second set of conductive lines.

Another example provides a device including an inductive device that includes a first packaged device and a second packaged device. The first packaged device includes a first body and a first conductor layer at least partially enclosed within the first body. The first conductor layer includes a first set of conductive lines arranged substantially parallel to one another. The first packaged device also includes a first set of external connectors coupled to the first set of conductive lines. Ends of the first set of external connectors are exposed on a face of the first body through openings in the first body. The second packaged device includes a second body and a second conductor layer at least partially enclosed within the second body. The second conductor layer includes a second set of conductive lines arranged substantially parallel to one another and at an angle relative to the first set of conductive lines. The second packaged device also includes a second set of external connectors coupled to the second conductor layer. Ends of the second set of external connectors are exposed on a face of the second body through openings in the second body. The first set of external connectors are coupled to the second set of external connectors to electrically connect the first set of conductive lines to the second set of conductive lines to define a coil having multiple turns, where each turn includes a conductive line of the first set of conductive lines and a conductive line of the second set of conductive lines.

Another example provides a method including providing a first packaged device that includes a first body and a first conductor layer at least partially enclosed within the first body. The first conductor layer includes a first set of conductive lines extending along a first direction and offset from one another in a second direction. The first packaged device also includes a first set of external connectors electrically connected to the first conductor layer and extending along a third direction, through openings in the first body, to a face of the first body. The method also includes providing a second packaged device that includes a second body and a second conductor layer at least partially enclosed within the second body. The second conductor layer includes a second set of conductive lines offset from one another in the second direction and extending along a fourth direction that is angularly offset from the first direction. The second packaged device also includes a second set of external connectors electrically connected to the second conductor layer and extending along the third direction, through openings in the second body, to a face of the second body. The method also includes coupling the first set of external connectors and the second set of external connectors to electrically connect the first set of conductive lines to the second set of conductive lines to define a coil having multiple turns, where each turn includes a conductive line of the first set of conductive lines and a conductive line of the second set of conductive lines.

Another example provides a transformer device (e.g., coupled inductors) including a first packaged device and a second packaged device. The first packaged device includes a first body and a first conductor layer at least partially enclosed within the first body. The first conductor layer includes a first set of conductive lines arranged substantially parallel to one another. The first packaged device also includes a first set of external connectors coupled to the first set of conductive lines, where ends of the first set of external connectors are exposed on a face of the first body through openings in the first body. The second packaged device includes a second body and a second conductor layer at least partially enclosed within the second body. The second conductor layer includes a second set of conductive lines and a set of jumpers. The second set of conductive lines are arranged substantially parallel to one another and at an angle relative to the first set of conductive lines. The second packaged device also includes a second set of external connectors coupled to the second conductor layer, where ends of the second set of external connectors are exposed on a face of the second body through openings in the second body. The first set of external connectors are coupled to the second set of external connectors to electrically connect the first set of conductive lines to the second set of conductive lines to define a first coil having multiple turns and a second coil having multiple turns.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a cross sectional profile view of an exemplary inductive device.

FIG. 1B illustrates top views of conductor layers of the exemplary inductive device of FIG. 1A.

FIG. 1C illustrates a top view of aspects of the exemplary inductive device of FIG. 1A.

FIG. 1D illustrates a perspective view of a current flow path of the exemplary inductive device of FIG. 1A.

FIG. 2A illustrates a cross sectional profile view of an exemplary inductive device.

FIG. 2B illustrates top views of conductor layers of the exemplary inductive device of FIG. 2A.

FIG. 2C illustrates a top view of aspects of the exemplary inductive device of FIG. 2A.

FIG. 2D illustrates a perspective view of current flow paths of the exemplary inductive device of FIG. 2A.

FIG. 3A illustrates a cross sectional profile view of an exemplary inductive device.

FIG. 3B illustrates top views of conductor layers of the exemplary inductive device of FIG. 3A.

FIG. 3C illustrates a top view of aspects of the exemplary inductive device of FIG. 3A.

FIG. 3D illustrates a perspective view of current flow paths of the exemplary inductive device of FIG. 3A.

FIG. 4 illustrates a cross sectional profile view of an exemplary inductive device.

FIG. 5 illustrates an exemplary sequence for fabricating a device including an exemplary inductive device.

FIG. 6 illustrates another exemplary sequence for fabricating a device including an exemplary inductive device.

FIG. 7 illustrates an exemplary flow diagram of a method for fabricating an exemplary inductive device.

FIG. 8 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

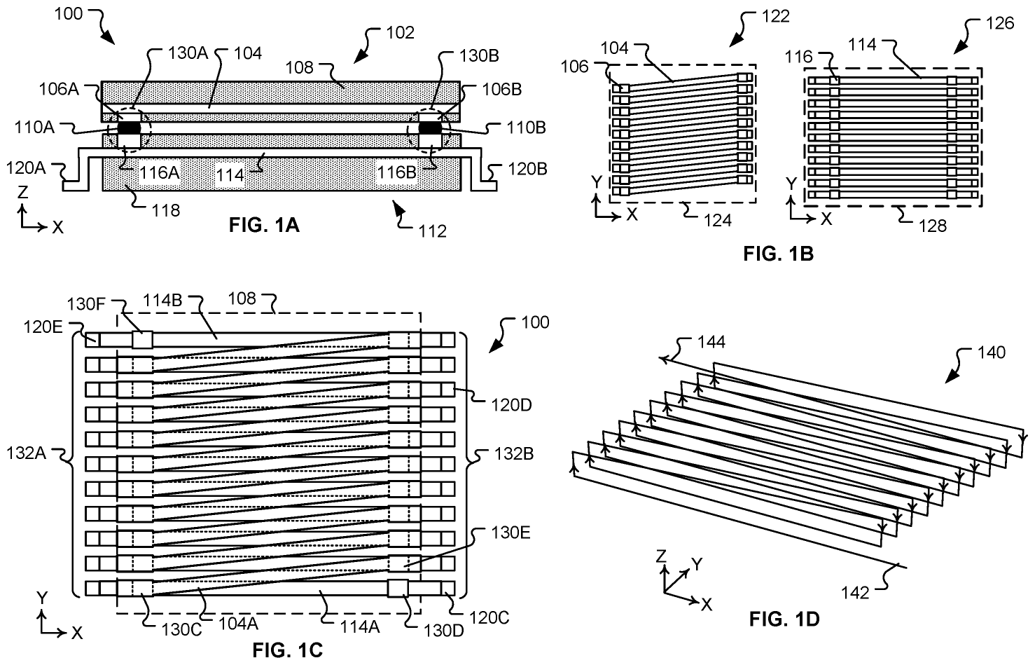

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 1A, multiple connectors 120 are illustrated and associated with reference numbers 120A and 120B. When referring to a particular one of these connectors, such as a connector 120A, the distinguishing letter “A” is used. However, when referring to any arbitrary one of these connectors or to these connectors as a group, the reference number 120 is used without a distinguishing letter.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Aspects of the present disclosure are directed to inductive devices that can be surface mounted and that can withstand large currents. Such inductive devices are increasingly in demand for high current applications, such as in the automotive industry. The disclosed inductive devices are simple and inexpensive to manufacture, while providing excellent electrical characteristics, such as high inductance and large maximum current density.

### Exemplary Inductive Device

FIGS. 1A-1D illustrate various aspects and views of an exemplary inductive device 100. In particular, FIG. 1A illustrates a cross sectional profile view of the inductive device 100, FIG. 1B illustrates top views of conductor layers of the inductive device 100, FIG. 1C illustrates a top view of conductive lines and electrical interconnects of the inductive device 100, and FIG. 1D illustrates a perspective view of a current flow path of the exemplary inductive device 100.

Referring to FIG. 1A, the inductive device 100 includes a first packaged device 112 and a second packaged device 102 that are stacked and electrically interconnected such that conductors of the packaged devices 102, 112 define a multi-turn coil. In this context, a “packaged” device refers to a device that includes one or more circuit elements (e.g., conductors) that are at least partially contained within a body and configured to be electrically connected to one or more other circuit elements external to the body. For example, a packaged device may include a discrete circuit element configured to be attached (e.g., surface mounted) to a circuit board.

The first packaged device 112 includes a first body 118 and a first conductor layer 126 (shown in FIG. 1B) at least partially enclosed within the first body 118. The first packaged device 112 also includes a first set of external connectors 116 that are electrically connected to the first conductor layer 126 and extend through openings in the first body 118 (e.g., in a direction along a Z axis illustrated in FIG. 1A) to a face (e.g., an upper surface in the view illustrated in FIG. 1A) of the first body 118.

In a particular implementation, the first body 118 includes a dielectric material, such as a mold compound. As an example, the first conductor layer 126 with the first set of external connectors 116 attached can be disposed in an uncured (e.g., liquid or paste) resin, which can subsequently be cured to form the first body 118. In this example, before the resin is cured, the ends of the external connectors 116 can be positioned to be approximately co-planar with or to extend past a surface of the resin such that the ends of the external connectors 116 are accessible after the resin is cured. Alternatively, the resin can cover the ends of the external connectors 116 after the resin is cured, and the first body 118 can be subjected to further processing (e.g., grinding, etching, etc.) to expose the ends of the external connectors 116.

The first conductor layer 126 includes a first set of conductive lines 114 that a extend along a first direction (e.g., parallel to an X axis in FIG. 1B). The conductive lines 114 are arranged substantially parallel to one another along the first direction and are offset from one another (e.g., spaced apart) in a second direction (e.g., in a direction parallel to the Y axis in FIG. 1B). In the example illustrated in FIG. 1B, each conductive line 114 is coupled to two external connectors 116 (e.g., one at each end of the conductive line 114). In some implementations, as described further below, one or more of the external connectors 116 is not used in the inductive device 100. In such implementations, unused external connectors 116 can be omitted from the first conductor layer 126.

In a particular aspect, the first conductor layer 126 can be a portion 128 of a lead frame structure. For example, a lead frame structure can be formed of one or more sheets or layers of metal (e.g., copper) which are processed (e.g., etched, stamped, cut, etc.) to define features of the lead frame structure. The lead frame structure can include, for example, multiple repeating units (e.g., multiple instances of the portion 128) arranged in a gird or side-by-side in a line. Optionally, the lead frame structure can also include support members between two or more of the portions 128. The portion 128 can be cut from or otherwise separated from the lead frame structure to form the layer 126. In some implementations, the lead frame structure can include both the conductive lines 114 and the external connectors 116. To illustrate, a layer of metal with a thickness greater than or equal to a combined thickness of a conductive line 114 and an external connector 116 can be patterned and/or etched to form the conductive lines 114, the external connectors 116, and other features of the lead frame structure. In another illustrative example, two or more metal layers can be joined to form the external connectors 116 on a layer that is subsequently processed to form the conductive lines 114 and other features of the lead frame structure. In other implementations, the external connectors 116 are joined to the conductive lines 114 after the lead frame structure is formed.

In the examples illustrated in FIGS. 1A-1C, the conductive lines 114 include connectors 120 (also referred to herein as external leads) on each side of the first packaged device 112. In some implementations, the lead frame structure or the conductive lines 114 are bent to form sets of connectors 132 (also referred to herein as external leads), including a first set of connectors 132A on a first side of the inductive device 100 and a second set of connectors 132B on a second side of the inductive device 100, as shown in FIG. 1C. For example, the conductive line 114 in FIG. 1A is bent on a first end to form an external lead (i.e., connector 120A) and is bent on a second end to form another external lead (i.e., connector 120B). The external leads (i.e., connectors 120) are configured to facilitate surface mounting of the inductive device 100 to a circuit board (e.g., a printed circuit board (PCB)).

The second packaged device 102 includes a second body 108 and a second conductor layer 122 (shown in FIG. 1B) at least partially enclosed within the second body 108. The second packaged device 102 also includes a second set of external connectors 106 that are electrically connected to the second conductor layer 122 and extend through openings in the second body 108 (e.g., in a direction along the Z axis illustrated in FIG. 1A) to a face (e.g., a lower surface in the view illustrated in FIG. 1A) of the second body 108.

In a particular implementation, the second body 108 includes a dielectric material, such as a mold compound (e.g., the same mold compound used to form the first body 118, or a different mold compound). For example, in some implementations, the second body 108 is formed in the same manner as and using the same materials as the first body 118. To illustrate, the second conductor layer 122 can be disposed in a resin that is subsequently cured to form the second body 108. The ends of the external connectors 106 can be exposed on the face of the second body 108 as a result of positioning of the second conductor layer 122 in the uncured resin or as a result of processing performed after the resin is cured.

The second conductor layer 122 includes a second set of conductive lines 104 that extend along a direction that is angularly offset from the direction along which the first set of conductive lines 114 extend (e.g., at an angle to the X axis in FIG. 1B). The conductive lines 104 are arranged substantially parallel to one another and are offset from one another (e.g., spaced apart) in a second direction (e.g., in a direction parallel to the Y axis in FIG. 1B). In the example illustrated in FIG. 1B, each conductive line 104 is coupled to two external connectors 106 (e.g., one at each end of the conductive line 104). In some implementations, as described further below, one or more of the external connectors 106 is not used in the inductive device 100. In such implementations, unused external connectors 106 can be omitted from the second conductor layer 122.

In a particular aspect, the second conductor layer 122 can be a portion 124 of a lead frame structure, such as described above with reference to the first conductor layer 126. The portion 124 can be cut or otherwise separated from the lead frame structure to form the layer 122. As explained with reference to the first conductor layer 126, the lead frame structure can include both the conductive lines 104 and optionally other features of the lead frame structure. In some implementations, the lead frame structure also includes the external connectors 106.

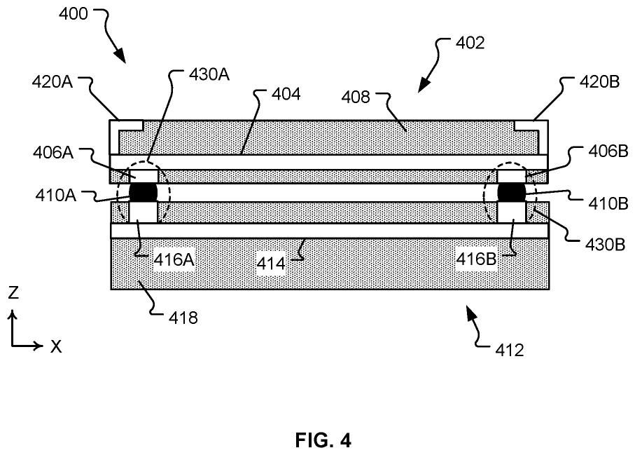

As illustrated in FIGS. 1A and 1B, ends of the conductive lines 104 do not extend significantly past sides of the second body 108. For example, the second packaged device 102 does not include external leads such as the connectors 120 of the first packaged device 112. Rather, ends of the conductive lines 104 are encapsulated within the second body 108 or approximately co-planar with sides of the second body 108. Thus, in the example illustrated in FIGS. 1A-1C, the first packaged device 112 is a surface mountable device similar to a quad-flat package (QFP) with sets of connectors 132 on two-sides rather than four sides, and the second packaged device 102 is a surface mountable device similar to a quad-flat no-lead (QFN) package or a dual-flat no-lead (DFN) package. As described in more detail with reference to FIG. 4, in some implementations, an inductive device can be formed using two packaged devices that use a configuration similar to the second packaged device 102 of FIG. 1A (e.g., two DFN packages).

In a particular aspect, a coil of the inductive device 100 includes conductive lines 114 of the first packaged device 112 and also includes conductive lines 104 of the second packaged device 102. For example, in FIG. 1A, solder balls 110 are used to join (e.g., electrically connect) the first set of external connectors 116 to the second set of external connectors 106, which electrically connects the first set of conductive lines 114 to the second set of conductive lines 104. To illustrate, a solder ball 110A electrically connects the external connector 116A to the external connector 106A to form an electrical interconnect 130A between a conductive line of the first set of conductive lines 114 and a conductive line of the second set of conductive lines 104. Similarly, a solder ball 110B electrically connects the external connector 116B to the external connector 106B to form an electrical interconnect 130B between a conductive line of the first set of conductive lines 114 and a conductive line of the second set of conductive lines 104.

FIG. 1C shows a top view of the sets of conductive lines 104, 114 and the electrical interconnects 130 of the inductive device 100 to more clearly illustrate a pattern of interconnects between the sets of conductive lines 104, 114 to form a coil. An outline of the shape of one or both of the bodies (e.g., the second body 108) is also shown in FIG. 1C. FIG. 1D illustrates a perspective view of a current path 140 formed by the pattern of interconnected conductive lines illustrated in FIG. 1C. In FIG. 1C, conductive lines of the second set of conductive lines 104 are disposed over portions of the conductive lines of the first set of conductive lines 114. As such, the second set of conductive lines 104 are illustrated with solid lines. Portions of the first set of conductive lines 114 that are visible in the top view of FIG. 1C are illustrated with solid lines, and obscured portions of the first set of conductive lines 114 and the electrical interconnects 130 are illustrated with broken (e.g., dashed or dotted) lines.

In the example illustrated in FIG. 1C, a connector 120C corresponds to an input to the inductive device 100, and a connector 120E corresponds to an output of the inductive device 100. For example, referring briefly to FIG. 1D, the connector 120C corresponds to an input 142 of the current path 140, and the connector 120E corresponds to an output 144 of the current path 140. Thus, current applied to connector 120C flows through a conductive line 114A of the first set of conductive lines 114 to an electrical interconnect 130C. The current flows through the electrical interconnect 130C to a conductive line 104A of the second set of conductive lines 104 and through the conductive line 104A to an electrical interconnect 130E. The electrical interconnect 130E connects the current to another conductive line of the first set of conductive lines 114, thus completing a single turn (or loop) of the coil. Other turns of the coil proceed in a similar manner. For example, each turn includes a conductive line of the first set of conductive lines 114, an electrical interconnect 130, a conductive line of the second set of conductive lines 104, and another electrical interconnect 130. In the example illustrated in FIG. 1C, after passing through ten turns of the coil, the current passes through a conductive line 114B of the first set of conductive lines 114 to the connector 120E.

In the example illustrated in FIG. 1C, electrical interconnects 130D and 130F are not used (e.g., do not form part of the current path 140). Accordingly, in some implementations, the electrical interconnects 130D and 130F or components thereof (e.g., an external connector 116 of the first packaged device 112, an external connector 106 of the second packaged device 102, and/or a solder ball 110) can be omitted from the inductive device 100. Alternatively, the inductive device 100 may include the electrical interconnects 130D and 130F for purposes other than forming part of the current path 140. For example, the electrical interconnects 130 provide mechanical support between the first and second packaged devices 112, 102, and retaining the electrical interconnects 130D and 130F (even though the electrical interconnects 130D and 130F do not form part of the current path 140) provides a more uniform distribution of mechanical supports.

Although FIG. 1C (and the current path 140 of FIG. 1D), illustrate using the connectors 120C and 120E as input/output connectors for the inductive device 100, in other implementations, other connectors 120 of the of the sets of connectors 132 can be used as input/output connectors for the inductive device 100. To illustrate, if a particular application (e.g., a particular circuit connected to the inductive device 100) needs an inductor with electrical characteristics representing 8 turns of the inductive device 100 rather than 10 turns, the inductive device 100 can be connected to the circuit via connectors 120C and 120D. Thus, the same inductive device 100 can be connected to different circuits in a manner that provides different electrical characteristics. Further, in some implementations, the inductive device 100 can be coupled to a circuit via a set of switches (e.g., transistors) to act as a variable inductor. For example, the connectors 120C, 120D, 120E, and possibly other connectors 120 of the sets of connectors 132 can be connected to a circuit via a set of switches. In this example, if a particular operation or configuration of the circuit needs inductance (or other electrical characteristics) associated with a coil of 10 turns, one or more switches of the circuit can be actuated to connect the connectors 120C and 120E as input/output connectors. Further, in this example, if a different operation or configuration of the circuit needs inductance (or other electrical characteristics) associated with a coil of 8 turns, one or more switches of the circuit can be actuated to connect the connectors 120C and 120D as input/output connectors. Any other arrangement of at least two connectors 120 can also, or alternatively, be used.

In some implementations, one or more of the connectors 120 of the sets of connectors 132 is not electrically connected to a circuit that uses the inductive device 100. For example, in some such implementations, the connectors 120C and 120E are electrically connected to a circuit, and the connector 120D is not electrically connected to the circuit. In such implementations, the connector(s) 120 that are not electrically connected to the circuit may nevertheless be physically connected to a circuit board associated with the circuit to provide mechanical support for the inductive device 100 and or to facilitate thermal management (e.g., heat dissipation).

In some implementations, a mold compound of either or both bodies 108, 118 can include a magnetic filler material (e.g., iron-containing particles or particles of another ferromagnetic material). In such implementations, the magnetic filler material can significantly increase inductance of the inductive device 100 as compared to a similar device that uses a non-magnetic filler material (e.g., silica). Additionally, simulation results indicate that use of a magnetic filler material also improves a low-frequency Q factor of the inductive device 100 as compared to a similar device that uses a non-magnetic filler material.

Since the inductance of an inductor is related to an area of an aperture of a coil of the inductor, the inductance of the inductive device 100 depends on the lengths of the conductive lines 104, 114 and the height of the electrical interconnects 130, which together define the area of the aperture of the coil of the inductive device 100. Accordingly, inductors having different electrical characteristics can be formed by changing the lengths of the conductive lines 104, 114, the positions of the electrical interconnects 130 along the conductive lines 104, 114, the height of the electrical interconnects 130, or any combination thereof. To illustrate, the first and second packaged device 112, 102 can be interconnected in different ways to form inductive devices 100 with different apertures (and therefore different electrical characteristics). For example, FIG. 1A illustrates solder balls 110 used to form the electrical interconnects 130; however, in other implementations, conductive posts and/or an interposer layer can be disposed between and electrically connected to the external connectors 116, 106 to form the electrical interconnects 130.

In addition to the benefits described above, another technical benefit of the inductive device 100 is that the conductive lines 104, 114 of the inductive device 100 are relatively thick (e.g., in a range between 50 and 150 micrometers) as compared to some legacy inductive devices that use wire(s) to connect conductive crossbars to form inductive turns. These large conductors of the inductive device 100 provide low DC resistance and high current capacity. An additional technical benefit is that the inductive device 100 is simple and low cost to manufacture. For example, there are no wire bonds in either body 118, 108, which means no wire bonding steps are needed to form the first or second packaged devices 112, 102. Rather, simple lead frame structures, devoid of wire bonds, can be encapsulated using a mold compound to form each of the first and second packaged devices 112, 102.

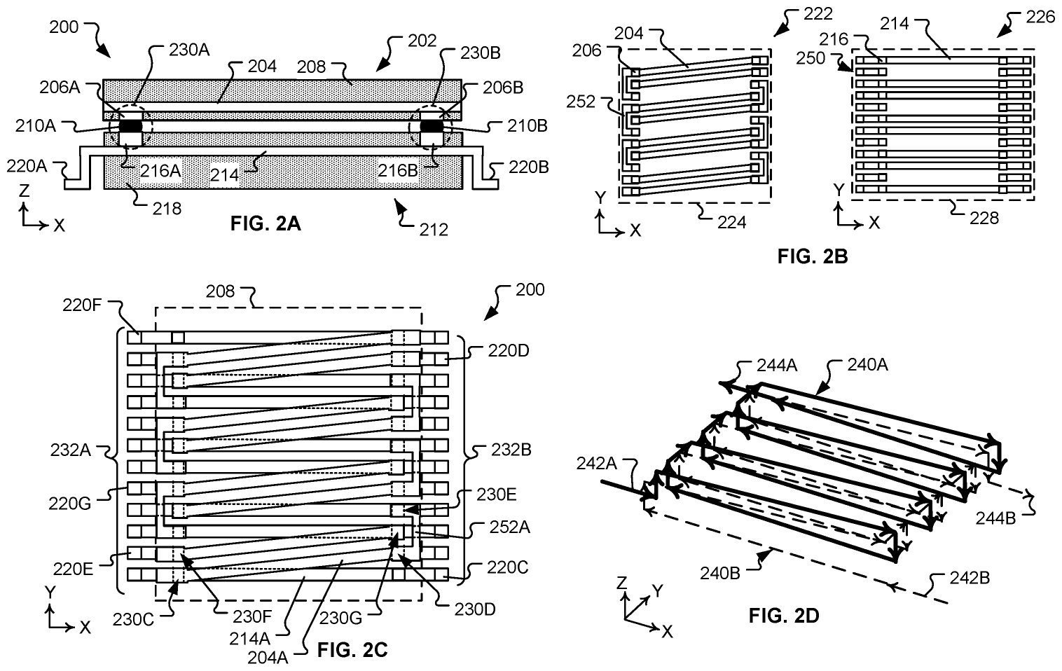

FIGS. 2A-2D illustrate various aspects and views of an exemplary inductive device 200. In particular, FIG. 2A illustrates a cross sectional profile view of the inductive device 200, FIG. 2B illustrates top views of conductor layers of the inductive device 200, FIG. 2C illustrates a top view of conductive lines and electrical interconnects of the inductive device 200, and FIG. 2D illustrates a perspective view of a current flow path of the exemplary inductive device 200.

Compared to the inductive device 100 of FIGS. 1A-1C, the inductive device 200 of FIGS. 2A-2C defines two inductive coils. For example, referring to FIG. 2D, a current path 240A of a first inductive coil of the inductive device 200 is illustrated in bold lines, and a current path 240B of a second inductive coil of the inductive device 200 is illustrated with dashed lines. To illustrate, in the example illustrated in FIG. 2D, an input 242A of the current path 240 of the first inductive coil is coupled to an output 244A of the current path 240A of the first inductive coil via four turns, and an input 242B of the current path 240B of the second inductive coil is coupled to an output 244B of the current path 240B of the second inductive coil via another four turns. The turns of the current path 240A are interleaved among the turns of the current path 240B such that a current flowing in one of the coils (e.g., along the current path 240A) induces current flow in the other coil (e.g. along the current path 240B). Thus, the inductive device 200 can operate as a set of coupled inductors (e.g., as a transformer).

Like the inductive device 100, the inductive device 200 includes a first packaged device 212 and a second packaged device 202. To form the inductive device 200, the first and second packaged devices 212, 202 are stacked and electrically interconnected such that conductors of the packaged devices 202, 212 define two multi-turn coils.

The first packaged device 212 includes a first body 218 and a first conductor layer 226 (shown in FIG. 2B) at least partially enclosed within the first body 218. The first packaged device 212 also includes a first set of external connectors 216 that are electrically connected to the first conductor layer 226 and extend through openings in the first body 218 (e.g., in a direction along a Z axis illustrated in FIG. 2A) to a face (e.g., an upper surface in the view illustrated in FIG. 2A) of the first body 218. The first body 218 includes a dielectric material, such as a mold compound, and optionally may include a magnetic filler material.

The first conductor layer 226 (e.g., a portion 228 of a lead frame structure) includes a first set of conductive lines 214 that a extend along a first direction (e.g., parallel to an X axis in FIG. 2B). The conductive lines 214 are arranged substantially parallel to one another along the first direction and are offset from one another (e.g., spaced apart) in a second direction (e.g., in a direction parallel to the Y axis in FIG. 2B). Each of the conductive lines 214 is coupled to at least one of the external connectors 216. Additionally, beginning with the second conductive line from either side, every third conductive line is discontinuous. To illustrate, a conductive line 250 includes a first end (e.g., on the left side in the orientation illustrated in FIG. 2B) and a second end (e.g., on the right side in the orientation illustrated in FIG. 2B) that are not electrically connected to one another.

As described with reference to FIGS. 1A-1C, in some implementations, the conductive lines 214 can be processed to form sets of connectors 232, such as a connector 220A and a connector 220B illustrated in FIG. 2A. In such implementations, the first packaged device 212 is similar to a double-flat package (DFP) with sets of connectors 232 on two sides. In other implementations, ends of the conductive lines 214 are encapsulated within the first body 218 or approximately co-planar with sides of the first body 218 to form a DFN package.

The second packaged device 202 includes a second body 208, a second conductor layer 222 (shown in FIG. 2B) at least partially enclosed within the second body 208, and a second set of external connectors 206 electrically connected to the second conductor layer 222 extending through openings in the second body 208 (e.g., in a direction along the Z axis illustrated in FIG. 2A) to a face (e.g., a lower surface in the view illustrated in FIG. 2A) of the second body 208. The second body 208 includes a dielectric material, such as a mold compound and optionally may include a magnetic filler material. The second conductor layer 222 (e.g., a portion 224 of a lead frame structure) includes a second set of conductive lines 204 that a extend along a direction that is angularly offset from the direction along which the first set of conductive lines 214 extend (e.g., at an angle to the X axis in FIG. 2B). The conductive lines 204 are arranged substantially parallel to one another and are offset from one another (e.g., spaced apart) in a second direction (e.g., in a direction parallel to the Y axis in FIG. 2B).

The second conductor layer 222 also include jumpers 252. Each jumper 252 connects two non-adjacent external connectors 206 (e.g., bypassing one external connector).

In a particular aspect, each coil of the inductive device 200 includes a subset of the conductive lines 214 of the first packaged device 212 and a subset of the conductive lines 204 of the second packaged device 202. For example, in FIG. 2A, a solder ball 210A electrically connects the external connector 216A to the external connector 206A to form an electrical interconnect 230A between a conductive line of the first set of conductive lines 214 and a conductive line of the second set of conductive lines 204. Similarly, a solder ball 210B electrically connects the external connector 216B to the external connector 206B to form an electrical interconnect 230B between a conductive line of the first set of conductive lines 214 and a conductive line of the second set of conductive lines 204.

FIG. 2C shows a top view of the sets of conductive lines 204, 214 and the electrical interconnects 230 of the inductive device 200 to more clearly illustrate a pattern of interconnects between the sets of conductive lines 204, 214 to form the coils of the inductive device 200. An outline of the shape of one or both of the bodies (e.g., the second body 208) is also shown in FIG. 2C. FIG. 2D illustrates a perspective view of the current paths 240A, 240B formed by the pattern of interconnected conductive lines illustrated in FIG. 2C.

In the example illustrated in FIG. 2C, a connector 220E corresponds to the input 242A of the current path 240A of a first coil of the inductive device 200, and a connector 220F corresponds to the output 244A of the first coil. Likewise, a connector 220C corresponds to the input 242B of the current path 240B of a second coil of the inductive device 200, and a connector 220D corresponds to the output 244B of the second coil. For example, a current applied to connector 220C flows through a conductive line 214A of the first set of conductive lines 214 to an electrical interconnect 230C. The current flows through the electrical interconnect 230C to a conductive line 204A of the second set of conductive lines 204 to an electrical interconnect 230D. The electrical interconnect 230D connects to a jumper 252A, which connects to an electrical interconnect 230E. The electrical interconnect 230E connects to another conductive line of the first set of conductive lines 214, thus completing a single turn of the second coil. Other turns of the second coil (except the last turn) proceed in a similar manner. For example, each turn except the last turn includes a conductive line of the first set of conductive lines 214, an electrical interconnect 230, a conductive line of the second set of conductive lines 204, a jumper 252, and another electrical interconnect 230. The last turn of the second coil does not include a jumper 252.

A current applied to the connector 220E follows a current path 240A that is reversed relative to the current path 240B described above. For example, the first coil does not include a jumper 252 in the first turn; however, each subsequent turn (including the last turn) of the first coil includes a jumper 252.

As described with reference to FIG. 1C, electrical interconnects 230 (or components thereof) that are unused as part of one of the current paths 240 can optionally be omitted. Alternatively, such electrical interconnects 230 can be retained to provide mechanical support.

As described with reference to FIG. 1C, different connectors 220 can be used as input/output connectors for the inductive device 200. For example, a connector 220G can be used as the input 242A for the current path 240A. In this example, the current path 240A includes three turns and the current path 240B includes four turns, enabling voltage conversion between the coils of the inductive device 200. Different winding ratios (e.g., a number of turns of one coil divided by a number of turns of the other coil) can be achieved based on which connectors 220 are used for input/output connectors of each coil. Additionally, the winding ratio can be statically configured based on electrical connection to a circuit or dynamically configured using switches. Connectors 220 that are not electrically connected to the circuit may be used to provide mechanical support for the inductive device 200 and or to facilitate thermal management (e.g., heat dissipation).

Although FIGS. 2A-2D describe an implementation in which each coil of the inductive device 200 includes four turns, this is merely one example. The pattern of conductive lines 204, 214, electrical interconnects 230, and jumpers 252 illustrated in FIGS. 2A-2C can be continued to form an inductive device 200 with more than four turns per coil or shortened to form an inductive device 200 with fewer than four turns per coil. Further, the lengths of the conductive lines 204, 214, the positions of the electrical interconnects 230 along the conductive lines 204, 214, and/or the height of the electrical interconnects 230 can be changed to form an inductive device 200 with different electrical characteristics. In summary, the inductive device 200 can be varied as described with reference to the inductive device 100 to achieve similar results as described above.

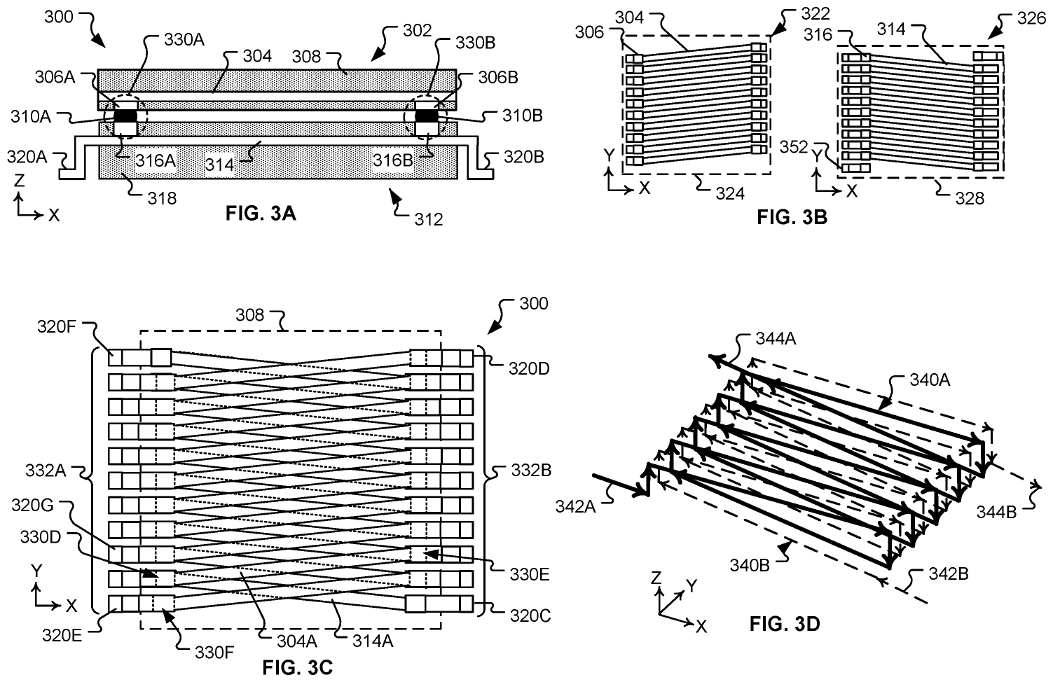

FIGS. 3A-3D illustrate various aspects and views of an exemplary inductive device 300. In particular, FIG. 3A illustrates a cross sectional profile view of the inductive device 300, FIG. 3B illustrates top views of conductor layers of the inductive device 300, FIG. 3C illustrates a top view of conductive lines and electrical interconnects of the inductive device 300, and FIG. 3D illustrates a perspective view of a current flow path of the exemplary inductive device 300.

Like the inductive device 200, the inductive device 300 includes two inductive coils. For example, referring to FIG. 3D, a current path 340A of a first inductive coil of the inductive device 300 is illustrated in bold lines, and a current path 340B of a second inductive coil of the inductive device 300 is illustrated with dashed lines. To illustrate, in the example illustrated in FIG. 3D, an input 342A of the current path 340A of the first inductive coil is coupled to an output 344A of the current path 340A of the first inductive coil via five turns, and an input 342B of the current path 340B of the second inductive coil is coupled to an output 344B of the current path 340B of the second inductive coil via another five turns. The turns of the current path 340A are interleaved among the turns of the current path 340B such that a current flowing in one of the coils (e.g., along the current path 340A) induces current flow in the other coil (e.g. along the current path 340B). Thus, the inductive device 300 can operate as a set of coupled inductors (e.g., as a transformer).

The inductive device 300 includes a first packaged device 312 and a second packaged device 302, which are stacked and electrically interconnected such that conductors of the packaged devices 302, 312 define two multi-turn coils. The first packaged device 312 includes a first body 318 and a first conductor layer 326 (shown in FIG. 3B) at least partially enclosed within the first body 318, and a first set of external connectors 316 that are electrically connected to the first conductor layer 326 and extend through openings in the first body 318 (e.g., in a direction along a Z axis illustrated in FIG. 3A) to a face (e.g., an upper surface in the view illustrated in FIG. 3A) of the first body 318. The first body 318 includes a dielectric material, such as a mold compound, and optionally may include a magnetic filler material.

The first conductor layer 326 (e.g., a portion 328 of a lead frame structure) includes a first set of conductive lines 314 that a extend along a first direction (e.g., at a first angle with respect to an X axis in FIG. 3B). The conductive lines 314 are arranged substantially parallel to one another along the first direction and are offset from one another (e.g., spaced apart) in a second direction (e.g., in a direction parallel to the Y axis in FIG. 3B). Each of the conductive lines 314 is coupled to at least one of the external connectors 316. Additionally, the first conductor layer 326 can include multiple connectors 352 that do not extend across the entirety of the first conductor layer 326.

As described with reference to FIGS. 1A-1C, in some implementations, the conductive lines 314 can be processed to form sets of connectors 332, such as a connector 320A and a connector 320B illustrated in FIG. 3A. In such implementations, the first packaged device 312 is similar to a double-flat package (DFP) with sets of connectors 332 on two-sides. In other implementations, ends of the conductive lines 314 are encapsulated within the first body 318 or approximately co-planar with sides of the first body 318 to form a DFN package.

The second packaged device 302 includes a second body 308, a second conductor layer 322 (shown in FIG. 3B) at least partially enclosed within the second body 308, and a second set of external connectors 306 electrically connected to the second conductor layer 322 extending through openings in the second body 308 (e.g., in a direction along the Z axis illustrated in FIG. 3A) to a face (e.g., a lower surface in the view illustrated in FIG. 3A) of the second body 308. The second body 308 includes a dielectric material, such as a mold compound and optionally may include a magnetic filler material. The second conductor layer 322 (e.g., a portion 324 of a lead frame structure) includes a second set of conductive lines 304 that extend along a direction that is angularly offset from the direction along which the first set of conductive lines 314 extend (e.g., at a second angle relative to the X axis in FIG. 3B). The conductive lines 304 are arranged substantially parallel to one another and are offset from one another (e.g., spaced apart) in a second direction (e.g., in a direction parallel to the Y axis in FIG. 3B).

In a particular aspect, each coil of the inductive device 300 includes a subset of the conductive lines 314 of the first packaged device 312 and a subset of the conductive lines 304 of the second packaged device 302. For example, in FIG. 3A, a solder ball 310A electrically connects the external connector 316A to the external connector 306A to form an electrical interconnect 330A between a conductive line of the first set of conductive lines 314 and a conductive line of the second set of conductive lines 304. Similarly, a solder ball 310B electrically connects the external connector 316B to the external connector 306B to form an electrical interconnect 330B between a conductive line of the first set of conductive lines 314 and a conductive line of the second set of conductive lines 304.

FIG. 3C shows a top view of the sets of conductive lines 304, 314 and the electrical interconnects 330 of the inductive device 300 to more clearly illustrate a pattern of interconnects between the sets of conductive lines 304, 314 to form the coils of the inductive device 300. An outline of the shape of one or both of the bodies (e.g., the second body 308) is also shown in FIG. 3C. FIG. 3D illustrates a perspective view of the current paths 340A, 340B formed by the pattern of interconnected conductive lines illustrated in FIG. 3C.

In the example illustrated in FIG. 3C, a connector 320E corresponds to the input 342A of the current path 340A of a first coil of the inductive device 300, and a connector 320F corresponds to the output 344A of the first coil. Likewise, a connector 320C corresponds to the input 342B of the current path 340B of a second coil of the inductive device 300, and a connector 320D corresponds to the output 344B of the second coil. For example, a current applied to the connector 320C flows through a conductive line 314A of the first set of conductive lines 314 to an electrical interconnect 330D. The current flows through the electrical interconnect 330D to a conductive line 304A of the second set of conductive lines 304 to an electrical interconnect 330E, thus completing a single turn of the second coil. Other turns of the second coil proceed in a similar manner. For example, each turn includes a conductive line of the first set of conductive lines 314, an electrical interconnect 330, a conductive line of the second set of conductive lines 304, and another electrical interconnect 330. A current applied to the connector 320E follows a current path 340A that is reversed relative to the current path 340B described above.

As described with reference to FIG. 1C, electrical interconnects 330 (or components thereof) that are unused as part of one of the current paths 340 can optionally be omitted. Alternatively, such electrical interconnects 330 can be retained to provide mechanical support.

As described with reference to FIGS. 1C and 2C, different connectors 320 can be used as input/output connectors for the inductive device 300. For example, a connector 320G can be used as the input 342A for the current path 340A. In this example, the current path 340A includes four turns and the current path 340B includes five turns, enabling voltage conversion between the coils of the inductive device 300. Different winding ratios (e.g., a number of turns of one coil divided by a number of turns of the other coil) can be achieved based on which connectors 320 are used for input/output connectors of each coil. Additionally, the winding ratio can be statically configured based on electrical connection to a circuit or dynamically configured using switches. Connectors 320 that are not electrically connected to the circuit may be used to provide mechanical support for the inductive device 300 and or to facilitate thermal management (e.g., heat dissipation).

Although FIGS. 3A-3D describe an implementation in which each coil of the inductive device 300 includes five turns, this is merely one example. The pattern of conductive lines 304, 314, and electrical interconnects 330 illustrated in FIGS. 3A-3C can be continued to form an inductive device 300 with more than five turns per coil or shortened to form an inductive device 300 with fewer than five turns per coil. Further, the lengths of the conductive lines 304, 314, the positions of the electrical interconnects 330 along the conductive lines 304, 314, and/or the height of the electrical interconnects 330 can be changed to form an inductive device 300 with different electrical characteristics. In summary, the inductive device 300 can be varied as described with reference to the inductive device 100 or the inductive device 200 to achieve similar results as described above.

FIG. 4 illustrates a cross sectional profile view of the inductive device 400. The inductive device 400 can include any of the configurations of conductive lines and electrical interconnects described with reference to FIGS. 1A-3D. For example, the inductive device 400 includes a first packaged device 412 and a second packaged device 402, which are stacked and electrically interconnected such that conductors of the packaged devices 402, 412 define a coil as described with reference to FIGS. 1A-1D, two coils as described with reference to FIGS. 2A-2D, or two coils as described with reference to FIGS. 3A-3D.

In the example illustrated in FIG. 4, the first packaged device 412 includes a first body 418 and a first conductor layer (e.g., a portion of a lead frame structure) including conductive lines 414 at least partially enclosed within the first body 418. A first set of external connectors 416 are electrically connected to the first conductor layer and extend through openings in the first body 418 (e.g., in a direction along a Z axis illustrated in FIG. 4) to a face (e.g., an upper surface in the view illustrated in FIG. 4) of the first body 418. The first body 418 includes a dielectric material, such as a mold compound, and optionally may include a magnetic filler material.

The second packaged device 402 includes a second body 408 and a second conductor layer (e.g. a portion of a lead frame structure) including conductive lines 404 at least partially enclosed within the second body 408. A second set of external connectors 406 are electrically connected to the second conductor layer and extend through openings in the second body 408 (e.g., in a direction along the Z axis illustrated in FIG. 4) to a face (e.g., a lower surface in the view illustrated in FIG. 4) of the second body 408. The second body 408 includes a dielectric material, such as a mold compound and optionally may include a magnetic filler material.

The first packaged device 412 is coupled to the second packaged device 402 via solder balls 410. The solder balls 410 together with the external electrical connectors 416, 406 form electrical interconnects 430 between the conductor layers of the first and second packaged devices 412, 402.

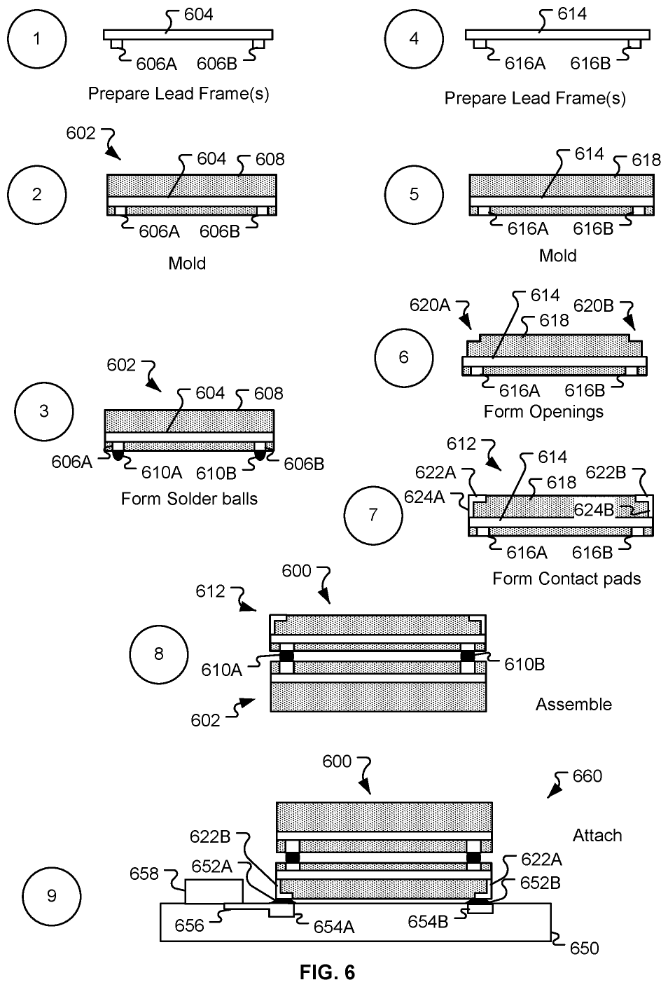

In the examples illustrated in FIGS. 1A-3D, ends of conductive lines of one of the conductor layers are used to form external leads. For example, in FIG. 1A, ends of the conductive lines 114 were bent to form the connectors 120. In contrast, in FIG. 4, connectors 420 are distinct from the first and second conductive lines 414, 404. To illustrate, the connectors 420 in FIG. 4 are electrically connected to conductive lines 404 (e.g., via plating, deposition, soldering, or another metal-to-metal joining process) as described further with reference to FIG. 6. The conductive lines 404 can correspond to any of the conductive lines 104, 114, 204, 214, 304, 314 described above, and each conductive line 404 can be electrically connected to a respective connector 420 or to a pair of connectors 420 (e.g., one on each end of the conductive line 404). Since the connectors 420 do not extend past sides of the inductive device 400, the inductive device 400 can have a smaller form factor than one of the inductive devices 100, 200, 300 while retaining the same inductor characteristics (e.g., the same count of turns, the same aperture, etc.).

### Exemplary Sequences for Fabricating a Device Including an Inductive Device

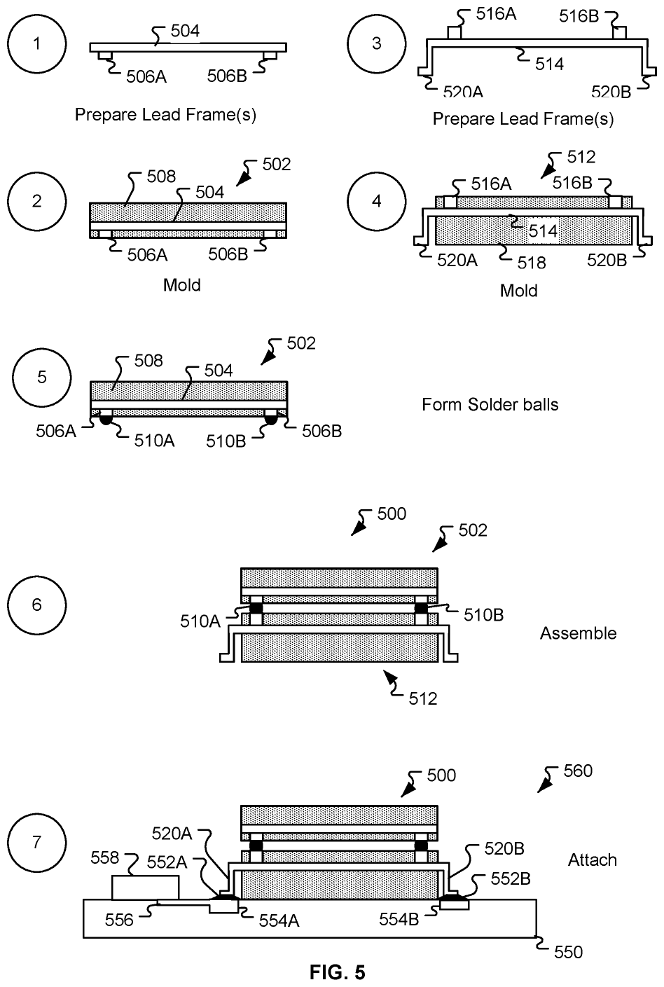

In some implementations, fabricating a device 560 that includes an inductive device 500 includes several processes. FIG. 5 illustrates a first exemplary sequence for providing or fabricating an inductive device 500, as described with reference to any of FIGS. 1A-3D, and optionally connecting the inductive device 500 to a device 560 that includes other circuitry. In some implementations, the sequence of FIG. 5 may be used to provide (e.g., during fabrication of) one or more of the inductive devices 100, 200, or 300 of FIGS. 1A-3D.

It should be noted that the sequence of FIG. 5 may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative stages of the sequence, which are numbered (using circled numbers) in FIG. 5. Each of the various stages of the sequence illustrated in FIG. 5 shows an individual component (e.g., the first packaged device 112, 212, 312; the second packaged device 102, 202, 302; or the inductive device 100, 200, or 300 of FIG. 1A, 2A, or 3A) being formed. In other implementations, two or more of at least some components can be formed concurrently. To illustrate, a lead frame structure used to form the first conductor layer 126, 226, or 326 of the first packaged device 112, 212, 312 can include multiple portions 128, 228, 328, which are encapsulated in mold compound before being separated from the lead frame structure to form individual components.

Stage 1 of FIG. 5 illustrates a state after preparation of a lead frame structure of the second packaged device 102, 202, 302 of FIG. 1A, 2A, or 3A. For example, the lead frame structure can be cut, etched, or otherwise patterned in a sheet of a conductive material to define various conductive lines 504 and external connectors 506A and 506B. The conductive lines 504 can be arranged as described with reference to any of FIG. 1B, 2B, or 3B. The external connectors 506 can be attached to the conductive lines 504 (e.g., using a metal-to-metal joining process, such as welding or soldering) or the external connectors 506 and the conductive lines 504 can be concurrently formed in a metal layer, such as by patterning the metal layer to define both the conductive lines 504 and the external connectors 506.

Stage 2 illustrates a state after a mold compound 508 is applied to at least partially encapsulate a portion of the lead frame structure of Stage 1. For example, the mold compound 508 can fully enclose the conductive lines 504 or can enclose all except ends of the conductive lines 504. Further, ends of the external connectors 506 are exposed through openings in the mold compound 508. In some implementations, the relative positions of the external connectors 506 and the surface of the mold compound 508 are controlled during application and hardening of the mold compound 508 to ensure that the ends of the external connectors 506 are exposed after hardening of the mold compound 508. In other implementations, a surface of the mold compound 508 is processed (e.g., etched or ground) to expose the ends of the external connectors 506 after hardening of the mold compound 508. The mold compound 508 includes a dielectric material, such as an epoxy resin, and optionally includes a magnetic filler material.

At Stage 2, fabrication of a second packaged device 502 is completed. For example, the second packaged device 502 includes a body defined by the mold compound 508. The second packaged device 502 also includes a conductor layer defining the conductive lines 504 and at least partially enclosed within the body. The conductive lines 504 are arranged to form any of the patterns or configurations described with reference to the second conductor layers 122, 222, 322 of FIG. 1B, 2B, or 3B. The second packaged device 502 also includes the external connectors 506, which are electrically connected to the conductive lines 504, and extend along a direction perpendicular to the conductive lines 504, through openings in the body, to a face of the body.

Stage 3 of FIG. 5 illustrates a state after preparation of a lead frame structure of the first packaged device 112, 212, 312 of FIG. 1A, 2A, or 3A. For example, the lead frame structure can be cut, etched, or otherwise patterned in a sheet of a conductive material to define various conductive lines 514, external connectors 516A and 516B, and connectors 520. The conductive lines 514 can be arranged as described with reference to any of FIG. 1B, 2B, or 3B. The external connectors 516 can be attached to the conductive lines 514 (e.g., using a metal-to-metal joining process, such as welding or soldering) or the external connectors 516 and the conductive lines 514 can be concurrently formed in a metal layer, such as by patterning the metal layer to define both the conductive lines 514 and the external connectors 516. Additionally, in the example illustrated in FIG. 5, the conductive lines 514 can be bent to form the connectors 520.

Stage 4 illustrates a state after a mold compound 518 is applied to at least partially encapsulate a portion of the lead frame structure of Stage 3. For example, the mold compound 518 can enclose the conductive lines 514 except for ends of the conductive lines 514 forming the connectors 520. Further, ends of the external connectors 516 are exposed through openings in the mold compound 518. In some implementations, the relative positions of the external connectors 516 and the surface of the mold compound 518 are controlled during application and hardening of the mold compound 518 to ensure that the ends of the external connectors 516 are exposed after hardening of the mold compound 518. In other implementations, a surface of the mold compound 518 is processed (e.g., etched or ground) to expose the ends of the external connectors 516 after hardening of the mold compound 518. The mold compound 518 includes a dielectric material, such as an epoxy resin, and optionally includes a magnetic filler material.

At Stage 4, fabrication of a first packaged device 512 is completed. For example, the first packaged device 512 includes a body defined by the mold compound 518. The first packaged device 512 also includes a conductor layer defining the conductive lines 514 and at least partially enclosed within the body. The conductive lines 514 are arranged to form any of the patterns or configurations described with reference to the first conductor layers 126, 226, 326 of FIG. 1B, 2B, or 3B. The first packaged device 512 also includes the external connectors 516, which are electrically connected to the conductive lines 514, and extend along a direction perpendicular to the conductive lines 514, through openings in the body, to a face of the body. Additionally, in the example illustrated in FIG. 5, the first packaged device 512 includes the connectors 520.

Stage 5 illustrates a state after solder balls 510 are formed on ends of the external connectors 506. Although FIG. 5 illustrates the solder balls 510 being formed on the second packaged device 502, in other implementations, the solder balls 510 are formed on the first packaged device 512. Additionally, although FIG. 5 illustrates solder balls used to connect the external connectors 506 of the second packaged device 502 and the external connectors 516 of the first packaged device 512, in other implementations, other electrical interconnect techniques and/or other electrical interconnect devices are used (in addition to or instead of the solder balls 510) to connect the external connectors 506 of the second packaged device 502 and the external connectors 516 of the first packaged device 512. For example, to form an inductive device with a larger coil aperture, an interposer device including conductive posts can be disposed between and electrically connected to the external connectors 506 and the external connectors 516.

Stage 6 illustrates a state after the first packaged device 512 and the second packaged device 502 are assembled (e.g., stacked and interconnected) together to form an inductive device 500. For example, a pick and place process can be used to stack the first and second packaged devices 512, 502, and a heating process can be used to reflow the solder balls 510 to electrically connect the external connectors 516 and the external connectors 506.

At Stage 6, fabrication of the inductive device 500 is completed. For example, the inductive device 500 includes the first packaged device 512 and the second packaged device 502. Further, conductive lines 504 of the second packaged device 502 are electrically connected (via the external connectors 506, the solder balls 510, and the external connectors 516) to the conductive lines 514 of the first packaged device 512 to define one or more coils having multiple turns. Each of the turns includes a conductive line of the conductive lines 514 and a conductive line of the conductive lines 504.

Stage 7 illustrates a state after attaching the inductive device 500 to a circuit board 550 to form a device 560 that includes the inductive device 500. For example, the connectors 520 of the inductive device 500 are used to surface mount the inductive device 500 to the circuit board 550. In this example, the circuit board 550 includes a plurality of pads 554 arranged to correspond to connectors 520 of the inductive device 500, and each connector 520 is coupled to a corresponding pad 554 using solder 552.

In some implementations, some of the connectors 520 are not electrically connected to circuitry of the circuit board 550. For example, in FIG. 5, a connector 520A is connected to a pad 554A of the circuit board 550. In this example, the pad 554A is electrically connected (via a conductor 556) to a component 558 of the circuit board 550. Thus, the connector 520A is electrically connected to circuitry of the circuit board 550. In contrast, a connector 520B is connected to pad 554B of the circuit board 550. Pad 554B is not connected to circuitry of the circuit board 550. Accordingly, the connector 520B is physically connected to the circuit board 550 (e.g., to provide mechanical support, thermal management, etc.), but does not operate as an input/output connector of an inductive coil of the inductive device 500.

Stages 1-4 are numbered sequentially in FIG. 5 merely for convenience of reference. In some implementations, the first and second packaged devices 512, 502 are fabricated in parallel. Further, in some implementations, the first and second packaged devices 512, 502 are fabricated beforehand and fabrication of the inductive device 500 includes assembly of first and second packaged devices 512, 502 at Stage 6.

In some implementations, fabricating a device 660 that includes an inductive device 600 includes several processes. FIG. 6 illustrates a second exemplary sequence for providing or fabricating an inductive device 600. The inductive device 600 corresponds to the inductive device 400 of FIG. 4, which as explained in the description of FIG. 4, can include conductive lines and electrical interconnects arranged in any of the configurations described with reference to FIG. 1C, 2C, or 3C. FIG. 6 also illustrates an optional process of connecting the inductive device 600 to a device 660 that includes other circuitry. As explained with reference to FIG. 5, the sequence of FIG. 6 can be modified, such as by combining one or more stages, performing operations in parallel, fabricating more than one component at a time, etc.

Stage 1 of FIG. 6 illustrates a state after preparation of a lead frame structure of the second packaged device 402 of FIG. 4. For example, the lead frame structure can be cut, etched, or otherwise patterned in a sheet of a conductive material to define various conductive lines 604 and external connectors 606A and 606B. The conductive lines 604 can be arranged as described with reference to any of FIG. 1B, 2B, or 3B. The external connectors 606 can be attached to the conductive lines 604 (e.g., using a metal-to-metal joining process, such as welding or soldering) or the external connectors 606 and the conductive lines 604 can be concurrently formed in a metal layer, such as by patterning the metal layer to define both the conductive lines 604 and the external connectors 606.

Stage 2 illustrates a state after a mold compound 608 is applied to at least partially encapsulate a portion of the lead frame structure of Stage 1. For example, the mold compound 608 can fully enclose the conductive lines 604 or can enclose all except ends of the conductive lines 604. Further, ends of the external connectors 606 are exposed through openings in the mold compound 608. In some implementations, the relative positions of the external connectors 606 and the surface of the mold compound 608 are controlled during application and hardening of the mold compound 608 to ensure that the ends of the external connectors 606 are exposed after hardening of the mold compound 608. In other implementations, a surface of the mold compound 608 is processed (e.g., etched or ground) to expose the ends of the external connectors 606 after hardening of the mold compound 608. The mold compound 608 includes a dielectric material, such as an epoxy resin, and optionally includes a magnetic filler material.

At Stage 2, fabrication of a second packaged device 602 is completed. For example, the second packaged device 602 includes a body defined by the mold compound 608. The second packaged device 602 also includes a conductor layer defining the conductive lines 604 and at least partially enclosed within the body. The conductive lines 604 are arranged to form any of the patterns or configurations described with reference to the second conductor layers 122, 222, 322 of FIG. 1B, 2B, or 3B. The second packaged device 602 also includes the external connectors 606, which are electrically connected to the conductive lines 604, and extend along a direction perpendicular to the conductive lines 604, through openings in the body, to a face of the body.

Stage 3 illustrates a state after solder balls 610 are formed on ends of the external connectors 606. Although FIG. 6 illustrates the solder balls 610 being formed on the second packaged device 602, in other implementations, the solder balls 610 are formed on a first packaged device 612. Additionally, although FIG. 6 illustrates solder balls used to connect the external connectors 606 of the second packaged device 602 and external connectors 616 of the first packaged device 612, in other implementations, other electrical interconnect techniques and/or other electrical interconnect devices are used (in addition to or instead of the solder balls 610) to connect the external connectors 606 of the second packaged device 602 and the external connectors 616 of the first packaged device 612. For example, to form an inductive device with a larger coil aperture, an interposer device including conductive posts can be disposed between and electrically connected to the external connectors 606 and the external connectors 616.

Stage 4 of FIG. 6 illustrates a state after preparation of a lead frame structure of the first packaged device 412 of FIG. 4. For example, the lead frame structure can be cut, etched, or otherwise patterned in a sheet of a conductive material to define various conductive lines 614 and external connectors 616A and 616B. The conductive lines 614 can be arranged as described with reference to any of FIG. 1B, 2B, or 3B. The external connectors 616 can be attached to the conductive lines 614 (e.g., using a metal-to-metal joining process, such as welding or soldering) or the external connectors 616 and the conductive lines 614 can be concurrently formed in a metal layer, such as by patterning the metal layer to define both the conductive lines 614 and the external connectors 616.

Stage 5 illustrates a state after a mold compound 618 is applied to at least partially encapsulate a portion of the lead frame structure of Stage 4. For example, the mold compound 618 can fully enclose the conductive lines 614 or can enclose all except ends of the conductive lines 614. Further, ends of the external connectors 616 are exposed through openings in the mold compound 618. In some implementations, the relative positions of the external connectors 616 and the surface of the mold compound 618 are controlled during application and hardening of the mold compound 618 to ensure that the ends of the external connectors 616 are exposed after hardening of the mold compound 618. In other implementations, a surface of the mold compound 618 is processed (e.g., etched or ground) to expose the ends of the external connectors 616 after hardening of the mold compound 618. The mold compound 618 includes a dielectric material, such as an epoxy resin, and optionally includes a magnetic filler material.

Stage 6 illustrates a state after openings 620 are formed in the mold compound 618 to expose portions of the conductive lines 614. In the example illustrated in FIG. 6, the openings 620 are formed along sides of a body defined by the mold compound 618; however, in other implementations, the openings 620 are formed at a distance from the sides of the body. Additionally, in the example illustrated in FIG. 6, the openings 620 include a vertical portion and a horizontal portion. In this example, the horizontal portion of each opening 620 corresponds to a recess on a face of the body for a contact pad 622 (illustrated at Stage 7), and the vertical portion of each opening 620 corresponds to a through mold via 624 to electrically connect the contact pad 622 to a respective one of the conductive lines 614. In some implementations, the contact pad 622 is attached to the face of the body rather than recessed into the body, in which case the horizontal portion of each opening 620 can be omitted. The openings 620 can be formed using etching, drilling, or other mold patterning techniques.

Stage 7 illustrates a state after the contact pads 622 and through mold vias 624 are formed. For example, metal can be plated or otherwise deposited within the openings 620 to form the contact pads 622 and through mold vias 624. In some implementations, the through mold vias 624 are formed using a first process, and the contact pads 622 are formed using a second process,

At Stage 7, a first packaged device 612 is completed. For example, the first packaged device 612 includes a body defined by the mold compound 618. The first packaged device 612 also includes a conductor layer defining the conductive lines 614 and at least partially enclosed within the body. The conductive lines 614 are arranged to form any of the patterns or configurations described with reference to the first conductor layers 126, 226, 326 of FIG. 1B, 2B, or 3B. The first packaged device 612 also includes the external connectors 616, which are electrically connected to the conductive lines 614, and extend along a direction perpendicular to the conductive lines 614, through openings in the body, to a face of the body. Additionally, in the example illustrated in FIG. 6, the first packaged device 612 includes the contact pads 622 which are electrically connected, by the through mold vias 624, to the conductive lines 614.

Stage 8 illustrates a state after the first packaged device 612 and the second packaged device 602 are assembled (e.g., stacked and interconnected) together to form the inductive device 600. For example, a pick and place process can be used to stack the first and second packaged devices 612, 602, and a heating process can be used to reflow the solder balls 610 to electrically connect the external connectors 616 and the external connectors 606.

At Stage 8, fabrication of the inductive device 600 is completed. For example, the inductive device 600 includes the first packaged device 612 and the second packaged device 602. Further, conductive lines 604 of the second packaged device 602 are electrically connected (via the external connectors 606, the solder balls 610, and the external connectors 616) to the conductive lines 614 of the first packaged device 612 to define one or more coils having multiple turns. Each of the turns includes a conductive line of the conductive lines 614 and a conductive line of the conductive lines 604.

Stage 9 illustrates a state after attaching the inductive device 600 to a circuit board 650 to form the device 660 that includes the inductive device 600. For example, the contact pads 622 of the inductive device 600 are used to surface mount the inductive device 600 to the circuit board 650. In this example, the circuit board 650 includes a plurality of pads 654 arranged to correspond to contact pads 622 of the inductive device 600, and each contact pads 622 is coupled to a corresponding pad 654 using solder 652.

In some implementations, some of the contact pads 622 are not electrically connected to circuitry of the circuit board 650. For example, in FIG. 6, a contact pad 622A is connected to a pad 654A of the circuit board 650. In this example, the pad 654A is electrically connected (via a conductor 656) to a component 658 of the circuit board 650. Thus, the contact pad 622A is electrically connected to circuitry of the circuit board 650. In contrast, a contact pad 622B is connected to pad 654B of the circuit board 650 that is not connected to circuitry of the circuit board 650. Accordingly, the contact pad 622B is physically connected to the circuit board 650 (e.g., to provide mechanical support, thermal management, etc.), but does not operate as an input/output connector of an inductive coil of the inductive device 600.

Stages 1-7 are numbered sequentially in FIG. 6 merely for convenience of reference. In some implementations, the first and second packaged devices 612, 602 are fabricated in parallel. Further, in some implementations, the first and second packaged devices 612, 602 are fabricated beforehand and fabrication of the inductive device 600 includes assembly of first and second packaged devices 612, 602 at Stage 8.

### Exemplary Flow Diagram of a Method for Fabricating an Inductive Device

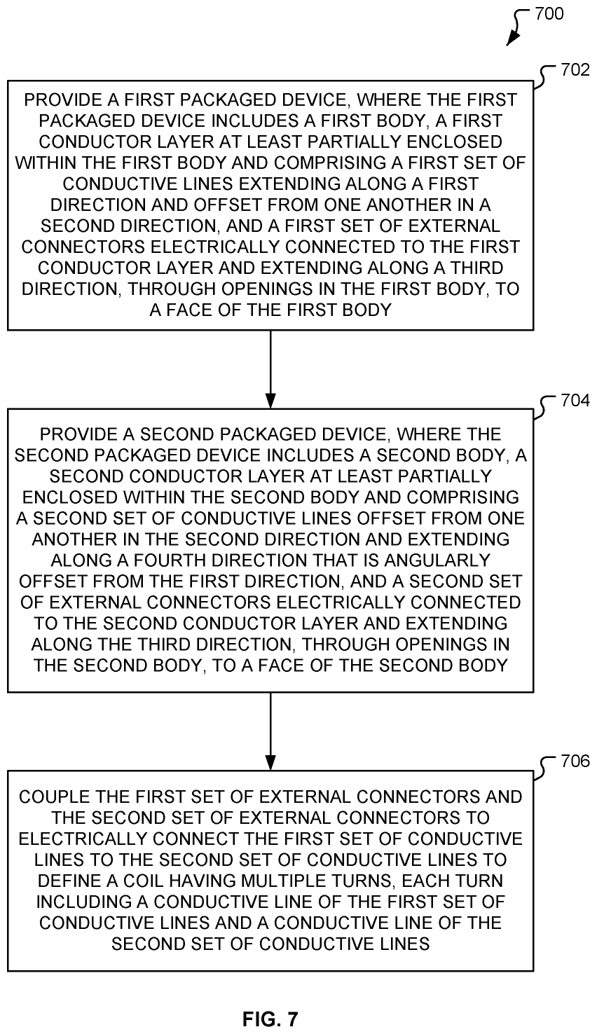

In some implementations, fabricating an inductive device includes several processes. FIG. 7 illustrates an exemplary flow diagram of a method 700 for providing or fabricating an inductive device. In some implementations, the method 700 of FIG. 7 may be used to provide or fabricate any of the inductive devices 100, 200, 300, 400, 500, or 600 of FIGS. 1A-6.

It should be noted that the method 700 of FIG. 7 may combine one or more processes in order to simplify and/or clarify the method for providing or fabricating an inductive device. In some implementations, the order of the processes may be changed or modified.

The method 700 includes, at block 702, providing a first packaged device, where the first packaged device includes a first body, a first conductor layer at least partially enclosed within the first body and comprising a first set of conductive lines extending along a first direction and offset from one another in a second direction, and a first set of external connectors electrically connected to the first conductor layer and extending along a third direction, through openings in the first body, to a face of the first body. For example, providing the first packaged device can include at least partially encapsulating the first conductor layer and the first set of external connectors in a mold compound and curing the mold compound to form the first body. In this example, the first conductor layer can include any of the conductor layers 126, 226, 326 of FIG. 1B, 2B, or 3B. In some implementations, the first conductor layer is part of a lead frame structure, in which case providing the first packaged device also includes separating the first conductor layer from the lead frame structure. For example, the first conductor layer can correspond to one of the portions 128, 228, 328 of a lead frame structure described with reference to FIGS. 1B, 2B, and 3B, respectively. One example of providing the first packaged device includes fabricating the first packaged device, as described with reference to Stages 3 and 4 of FIG. 5 or Stages 4-7 of FIG. 6.

The method 700 includes, at block 704, providing a second packaged device, where the second packaged device includes a second body, a second conductor layer at least partially enclosed within the second body and comprising a second set of conductive lines offset from one another in the second direction and extending along a fourth direction that is angularly offset from the first direction, and a second set of external connectors electrically connected to the second conductor layer and extending along the third direction, through openings in the second body, to a face of the second body. For example, providing the second packaged device can include at least partially encapsulating the second conductor layer and the second set of external connectors in a mold compound and curing the mold compound to form the second body. In this example, the second conductor layer can include any of the conductor layers 122, 222, 322 of FIG. 1B, 2B, or 3B. In some implementations, the second conductor layer is part of a lead frame structure, in which case providing the second packaged device also includes separating the second conductor layer from the lead frame structure. For example, the second conductor layer can correspond to one of the portions 124, 224, 324 of a lead frame structure described with reference to FIGS. 1B, 2B, and 3B, respectively. One example of providing the second packaged device includes fabricating the second packaged device, as described with reference to Stages 1 and 2 of FIG. 5 or Stages 1 and 2 of FIG. 6.

The method 700 also includes, at block 706, coupling the first set of external connectors and the second set of external connectors to electrically connect the first set of conductive lines to the second set of conductive lines to define a coil having multiple turns, each turn including a conductive line of the first set of conductive lines and a conductive line of the second set of conductive lines. For example, the first and second packaged devices can be electrically connected to form any of the current paths 140, 240, or 340 of FIGS. 1D, 2D, and 3D. In some implementations, electrically connecting the first set of conductive lines to the second set of conductive lines to defines at least two coils, each having multiple turns, such as either of the coils described with reference to FIG. 2A-2D or 3A-3D. Assembling the inductive device 500 as described with reference to Stage 6 of FIG. 5 and assembling the inductive device 600 as described with reference Stage 8 of FIG. 6 are two examples of coupling the first set of external connectors and the second set of external connectors to electrically connect the first set of conductive lines to the second set of conductive lines to define a coil having multiple turns.

In some implementations, the method 700 also includes electrically connecting the coil to one or more circuit components of a circuit board via at least two external leads of a set of external leads. For example, as described with reference to Stage 7 of FIG. 5, the inductive device 500 can be surface mounted to the circuit board 550 via the connectors 520. In this example, the connector 520A is electrically connected to component 558 of a circuit board 550. As described with reference to FIGS. 1C, 2C, and 3C, at least two of the connectors 120, 220, 320 are used as input/output connectors of the coil.

In some implementations, the method 700 includes physically connecting at least one external lead of the set of external leads to the circuit board without forming an electrical connection between the at least one external lead and any circuit component of the circuit board. For example, as described with reference to Stage 7 of FIG. 5, the connector 520B is physically connected to the pad 554B, which is not electrically connected to circuitry of the circuit board 550.

### Exemplary Electronic Devices

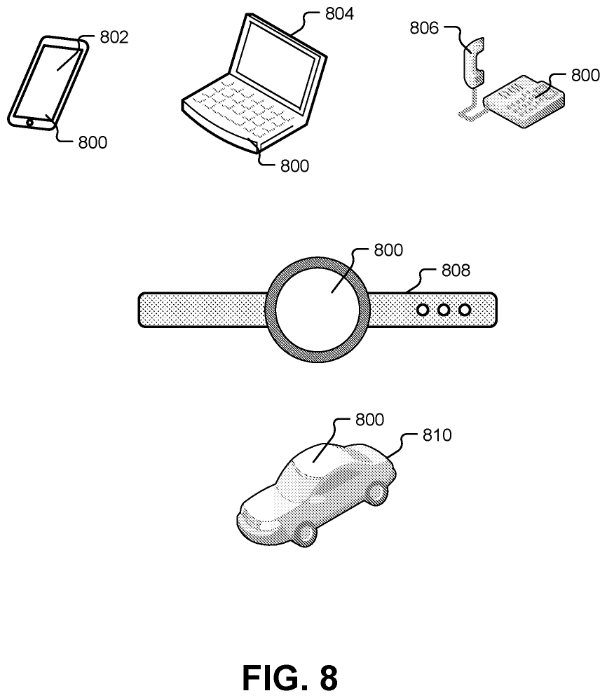

FIG. 8 illustrates various electronic devices that may include or be integrated with any of the inductive devices 100, 200, 300, 400, 500, or 600. For example, a mobile phone device 802, a laptop computer device 804, a fixed location terminal device 806, a wearable device 808, or a vehicle 810 (e.g., an automobile or an aerial device) may include a device 800. The device 800 can include, for example, any of the inductive devices 100, 200, 300, 400, 500, or 600 described herein. The devices 802, 804, 806 and 808 and the vehicle 810 illustrated in FIG. 8 are merely exemplary. Other electronic devices may also feature the device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-8 may be rearranged and/or combined into a single component, process, feature or function or embodied in several components, processes, or functions. Additional elements, components, processes, and/or functions may also be added without departing from the disclosure. In some implementations, FIGS. 1A-8 and the corresponding descriptions may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, an inductive device includes a first packaged device that includes a first body; a first conductor layer at least partially enclosed within the first body and comprising a first set of conductive lines extending along a first direction and offset from one another in a second direction; and a first set of external connectors electrically connected to the first conductor layer and extending along a third direction, through openings in the first body, to a face of the first body; and a second packaged device that includes a second body; a second conductor layer at least partially enclosed within the second body and comprising a second set of conductive lines offset from one another in the second direction and extending along a fourth direction that is angularly offset from the first direction; and a second set of external connectors electrically connected to the second conductor layer and extending along the third direction, through openings in the second body, to a face of the second body; wherein the first set of external connectors is coupled to the second set of external connectors to electrically connect the first set of conductive lines to the second set of conductive lines to define a coil having multiple turns, each turn including a conductive line of the first set of conductive lines and a conductive line of the second set of conductive lines.

Example 2 includes the inductive device of Example 1, wherein ends of the first set of conductive lines extend along the first direction past one or more sides of the first body.

Example 3 includes the inductive device of Example 1 or Example 2, wherein a first end of each of the first set of conductive lines extends past a first side of the first body, and a second end of each of the first set of conductive lines extends past a second side of the first body, and wherein the first side is opposite the second side.

Example 4 includes the inductive device of any of Examples 1 to 3, wherein the first packaged device is a first surface mountable device and the second packaged device is a second surface mountable device.

Example 5 includes the inductive device of any of Examples 1 to 4, wherein each turn of the coil further includes two external connectors of the first set of external connectors, two external connectors of the second set of external connectors, a first electrical interconnect between a first external connector of the first set of external connectors and a first external connector of the second set of external connectors, and a second electrical interconnect between a second external connector of the second set of external connectors and a second external connector of the first set of external connectors.

Example 6 includes the inductive device of Example 5, wherein the first electrical interconnect and the second electrical interconnect comprise solder balls, conductive posts, an interposer device, or a combination thereof.

Example 7 includes the inductive device of any of Examples 1 to 6, wherein the first body, the second body, or both, comprise mold compound.

Example 8 includes the inductive device of any of Examples 1 to 7, wherein the first body, the second body, or both, comprise a magnetic filler material.

Example 9 includes the inductive device of any of Examples 1 to 8, wherein each conductive line of the first set of conductive lines and each conductive line of the second set of conductive lines has a thickness, measured along the third direction, of between 50 and 150 micrometers.

Example 10 includes the inductive device of any of Examples 1 to 9, wherein the first packaged device and the second packaged device are devoid of wirebonds.

Example 11 includes the inductive device of any of Examples 1 to 10, wherein a first external connector coupled to a first conductive line of the first set of conductive lines is coupled to a first external connector that is coupled to a first conductive line of the second set of conductive lines, and a second external connector coupled to the first conductive line of the first set of conductive lines is coupled to a second external connector that is coupled to a second conductive line of the second set of conductive lines, and wherein the second conductive line of the second set of conductive lines is adjacent to the first conductive line of the second set of conductive lines in the second conductor layer.

Example 12 includes the inductive device of any of Examples 1 to 10, wherein a first external connector coupled to a first conductive line of the first set of conductive lines is coupled to a first external connector that is coupled to a first conductive line of the second set of conductive lines, and a second external connector coupled to the first conductive line of the first set of conductive lines is coupled to a second external connector that is coupled to a second conductive line of the second set of conductive lines, and wherein at least one third conductive line of the second set of conductive lines is disposed between the second conductive line of the second set of conductive lines and the first conductive line of the second set of conductive lines in the second conductor layer.

Example 13 includes the inductive device of any of Examples 1 to 10, wherein the second conductor layer further comprises a set of jumpers, wherein each jumper of the set of jumpers connects to two non-adjacent external connectors of the second set of external connectors.

According to Example 14, a device includes an inductive device including a first packaged device that includes a first body; a first conductor layer at least partially enclosed within the first body and comprising a first set of conductive lines arranged substantially parallel to one another; and a first set of external connectors coupled to the first set of conductive lines, wherein ends of the first set of external connectors are exposed on a face of the first body through openings in the first body; and a second packaged device that includes a second body; a second conductor layer at least partially enclosed within the second body and comprising a second set of conductive lines arranged substantially parallel to one another and at an angle relative to the first set of conductive lines; and a second set of external connectors coupled to the second conductor layer, wherein ends of the second set of external connectors are exposed on a face of the second body through openings in the second body; wherein the first set of external connectors are coupled to the second set of external connectors to electrically connect the first set of conductive lines to the second set of conductive lines to define a coil having multiple turns, each turn including a conductive line of the first set of conductive lines and a conductive line of the second set of conductive lines.

Example 15 includes the device of Example 14, wherein the first body comprises: a second face opposite the face of the first body exposing the first set of external electrical connectors; and one or more sides between the face and the second face, and wherein ends of the first set of conductive lines extend past the one or more sides to form a set of external leads.

Example 16 includes the device of Example 14 or Example 15, further comprising a circuit board comprising a plurality of circuit components, wherein at least two external leads of the set of external leads are electrically connected to one or more circuit components of the plurality of circuit components.

Example 17 includes the device of Examples 16, wherein at least one external lead of the set of external leads is physically connected to the circuit board and is not electrically connected to the plurality of circuit components.

Example 18 includes the device of Example 16 or Example 17, wherein the inductive device is surface mounted to the circuit board via the set of external leads.

Example 19 includes the device of any of Examples 14 to 18, wherein each turn of the coil further includes two external connectors of the first set of external connectors, two external connectors of the second set of external connectors, a first electrical interconnect between a first external connector of the first set of external connectors and a first external connector of the second set of external connectors, and a second electrical interconnect between a second external connector of the second set of external connectors and a second external connector of the first set of external connectors.

Example 20 includes the device of Example 19, wherein the first electrical interconnect and the second electrical interconnect comprise solder balls, conductive posts, an interposer device, or a combination thereof.

Example 21 includes the device of any of Examples 14 to 20, wherein the first body, the second body, or both, comprise mold compound.

Example 22 includes the device of any of Examples 14 to 21, wherein the first body, the second body, or both, comprise a magnetic filler material.

Example 23 includes the device of any of Examples 14 to 22, wherein each conductive line of the first set of conductive lines and each conductive line of the second set of conductive lines has a thickness of between 50 and 150 micrometers.

Example 24 includes the device of any of Examples 14 to 23, wherein the first packaged device and the second packaged device are devoid of wirebonds.

Example 25 includes the device of any of Examples 14 to 24, wherein a first external connector coupled to a first conductive line of the first set of conductive lines is coupled to a first external connector that is coupled to a first conductive line of the second set of conductive lines, and a second external connector coupled to the first conductive line of the first set of conductive lines is coupled to a second external connector that is coupled to a second conductive line of the second set of conductive lines, and wherein the second conductive line of the second set of conductive lines is adjacent to the first conductive line of the second set of conductive lines in the second conductor layer.

Example 26 includes the device of any of Examples 14 to 24, wherein a first external connector coupled to a first conductive line of the first set of conductive lines is coupled to a first external connector that is coupled to a first conductive line of the second set of conductive lines, and a second external connector coupled to the first conductive line of the first set of conductive lines is coupled to a second external connector that is coupled to a second conductive line of the second set of conductive lines, and wherein at least one third conductive line of the second set of conductive lines is disposed between the second conductive line of the second set of conductive lines and the first conductive line of the second set of conductive lines in the second conductor layer.

Example 27 includes the device of any of Examples 14 to 24, wherein the second conductor layer further comprises a set of jumpers, wherein each jumper of the set of jumpers connects to two non-adjacent external connectors of the second set of external connectors.

According to Example 28, a method includes providing a first packaged device that includes a first body; a first conductor layer at least partially enclosed within the first body and comprising a first set of conductive lines extending along a first direction and offset from one another in a second direction; and a first set of external connectors electrically connected to the first conductor layer and extending along a third direction, through openings in the first body, to a face of the first body; providing a second packaged device that includes a second body; a second conductor layer at least partially enclosed within the second body and comprising a second set of conductive lines offset from one another in the second direction and extending along a fourth direction that is angularly offset from the first direction; and a second set of external connectors electrically connected to the second conductor layer and extending along the third direction, through openings in the second body, to a face of the second body; and coupling the first set of external connectors and the second set of external connectors to electrically connect the first set of conductive lines to the second set of conductive lines to define a coil having multiple turns, each turn including a conductive line of the first set of conductive lines and a conductive line of the second set of conductive lines.

Example 29 includes the method of Example 28, wherein ends of the first set of conductive lines extend along the first direction past one or more sides of the first body to define a set of external leads.

Example 30 includes the method of Example 28 or Example 29, further comprising electrically connecting the coil to one or more circuit components of a circuit board via at least two external leads of the set of external leads.

Example 31 includes the method of Example 30 and further includes physically connecting at least one external lead of the set of external leads to the circuit board without forming an electrical connection between the at least one external lead and any circuit component of the circuit board.

Example 32 includes the method of any of Examples 28 to 31 and further includes surface mounting the first packaged device to a circuit board.

Example 33 includes the method of any of Examples 28 to 32, wherein each turn of the coil further includes two external connectors of the first set of external connectors, two external connectors of the second set of external connectors, a first electrical interconnect between a first external connector of the first set of external connectors and a first external connector of the second set of external connectors, and a second electrical interconnect between a second external connector of the second set of external connectors and a second external connector of the first set of external connectors.

Example 34 includes the method of Example 33, wherein the first electrical interconnect and the second electrical interconnect comprise solder balls, conductive posts, an interposer device, or a combination thereof.

Example 35 includes the method of any of Examples 28 to 34, wherein providing the first packaged device comprises: at least partially encapsulating the first conductor layer and the first set of external connectors in a mold compound; and curing the mold compound to form the first body.

Example 36 includes the method of Example 35, wherein the first conductor layer comprises a portion of a lead frame structure, and further comprising separating the first conductor layer from the lead frame structure.

Example 37 includes the method of Example 35 or Example 36, wherein the mold compound comprises a magnetic filler material.

Example 38 includes the method of any of Examples 28 to 37, wherein providing the second packaged device comprises: at least partially encapsulating the second conductor layer and the second set of external connectors in a mold compound; and curing the mold compound to form the second body.

Example 39 includes the method of Example 38, wherein the second conductor layer comprises a portion of a lead frame structure, and further comprising separating the second conductor layer from the lead frame structure.

Example 40 includes the method of Example 38 or Example 39, wherein the mold compound comprises a magnetic filler material.

Example 41 includes the method of any of Examples 28 to 40, wherein a first external connector coupled to a first conductive line of the first set of conductive lines is coupled to a first external connector that is coupled to a first conductive line of the second set of conductive lines, and a second external connector coupled to the first conductive line of the first set of conductive lines is coupled to a second external connector that is coupled to a second conductive line of the second set of conductive lines, and wherein the second conductive line of the second set of conductive lines is adjacent to the first conductive line of the second set of conductive lines in the second conductor layer.

Example 42 includes the method of any of Examples 28 to 40, wherein a first external connector coupled to a first conductive line of the first set of conductive lines is coupled to a first external connector that is coupled to a first conductive line of the second set of conductive lines, and a second external connector coupled to the first conductive line of the first set of conductive lines is coupled to a second external connector that is coupled to a second conductive line of the second set of conductive lines, and wherein at least one third conductive line of the second set of conductive lines is disposed between the second conductive line of the second set of conductive lines and the first conductive line of the second set of conductive lines in the second conductor layer.

Example 43 includes the method of any of Examples 28 to 40, wherein the second conductor layer further comprises a set of jumpers, wherein each jumper of the set of jumpers connects to two non-adjacent external connectors of the second set of external connectors.

According to Example 44, a transformer device includes a first packaged device that includes a first body; a first conductor layer at least partially enclosed within the first body and comprising a first set of conductive lines arranged substantially parallel to one another; and a first set of external connectors coupled to the first set of conductive lines, wherein ends of the first set of external connectors are exposed on a face of the first body through openings in the first body; and a second packaged device that includes a second body; a second conductor layer at least partially enclosed within the second body and comprising a second set of conductive lines and a set of jumpers, wherein the second set of conductive lines are arranged substantially parallel to one another and at an angle relative to the first set of conductive lines; and a second set of external connectors coupled to the second conductor layer, wherein ends of the second set of external connectors are exposed on a face of the second body through openings in the second body; wherein the first set of external connectors are coupled to the second set of external connectors to electrically connect the first set of conductive lines to the second set of conductive lines to define a first coil having multiple turns and a second coil having multiple turns.

Example 45 includes the transformer device of Example 44, wherein the first body comprises: a second face opposite the face of the first body exposing the first set of external electrical connectors; and one or more sides between the face and the second face, and wherein ends of the first set of conductive lines extend past the one or more sides to form a set of external leads.

Example 46 includes the transformer device of Example 44 or Example 45, wherein the first packaged device is a first surface mountable device and the second packaged device is a second surface mountable device.

Example 47 includes the transformer device of any of Examples 44 to 46, wherein a particular turn of the first coil includes a first conductive line of the first set of conductive lines, a first external connector of the first set of external connectors, a first electrical interconnect, a first external connector of the second set of external connectors, a first conductive line of the second set of conductive lines, a jumper of the set of jumpers, a second external connector of the second set of external connectors, a second electrical interconnect, and a second external connector of the first set of connectors.

Example 48 includes the transformer device of Example 47, wherein the first electrical interconnect and the second electrical interconnect comprise solder balls, conductive posts, an interposer device, or a combination thereof.

Example 49 includes the transformer device of any of Examples 44 to 48, wherein the first body, the second body, or both, comprise mold compound.

Example 50 includes the transformer device of any of Examples 44 to 49, wherein the first body, the second body, or both, comprise a magnetic filler material.

Example 51 includes the transformer device of any of Examples 44 to 50, wherein each conductive line of the first set of conductive lines and each conductive line of the second set of conductive lines has a thickness of between 50 and 150 micrometers.

Example 52 includes the transformer device of any of Examples 44 to 51, wherein the first packaged device and the second packaged device are devoid of wirebonds.

Example 53 includes the transformer device of any of Examples 44 to 52, wherein each jumper of the set of jumpers connects to two non-adjacent external connectors of the second set of external connectors.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An inductive device comprising:
a first packaged device comprising:
a first body;
a first conductor layer at least partially enclosed within the first body and comprising a first set of conductive lines extending along a first direction and offset from one another in a second direction; and
a first set of external connectors electrically connected to the first conductor layer and extending along a third direction, through openings in the first body, to a face of the first body; and
a second packaged device comprising:
a second body;
a second conductor layer at least partially enclosed within the second body and comprising a second set of conductive lines offset from one another in the second direction and extending along a fourth direction that is angularly offset from the first direction; and
a second set of external connectors electrically connected to the second conductor layer and extending along the third direction, through openings in the second body, to a face of the second body; and
wherein the first set of external connectors is coupled to the second set of external connectors to electrically connect the first set of conductive lines to the second set of conductive lines to define a coil having multiple turns, each turn including a conductive line of the first set of conductive lines and a conductive line of the second set of conductive lines.

2. The inductive device of claim 1, wherein a first end of each of the first set of conductive lines extends past a first side of the first body, and a second end of each of the first set of conductive lines extends past a second side of the first body, and wherein the first side is opposite the second side.

3. The inductive device of claim 1, wherein the first packaged device is a first surface mountable device and the second packaged device is a second surface mountable device.

4. The inductive device of claim 1, wherein each turn of the coil further includes two external connectors of the first set of external connectors, two external connectors of the second set of external connectors, a first electrical interconnect between a first external connector of the first set of external connectors and a first external connector of the second set of external connectors, and a second electrical interconnect between a second external connector of the second set of external connectors and a second external connector of the first set of external connectors.

5. The inductive device of claim 4, wherein the first electrical interconnect and the second electrical interconnect comprise solder balls, conductive posts, an interposer device, or a combination thereof.

6. The inductive device of claim 1, wherein the first body, the second body, or both, comprise mold compound including a magnetic filler material.

7. The inductive device of claim 1, wherein each conductive line of the first set of conductive lines and each conductive line of the second set of conductive lines has a thickness, measured along the third direction, of between 50 and 150 micrometers.

8. The inductive device of claim 1, wherein a first external connector coupled to a first conductive line of the first set of conductive lines is coupled to a first external connector that is coupled to a first conductive line of the second set of conductive lines, and a second external connector coupled to the first conductive line of the first set of conductive lines is coupled to a second external connector that is coupled to a second conductive line of the second set of conductive lines, and wherein the second conductive line of the second set of conductive lines is adjacent to the first conductive line of the second set of conductive lines in the second conductor layer.

9. The inductive device of claim 1, wherein a first external connector coupled to a first conductive line of the first set of conductive lines is coupled to a first external connector that is coupled to a first conductive line of the second set of conductive lines, and a second external connector coupled to the first conductive line of the first set of conductive lines is coupled to a second external connector that is coupled to a second conductive line of the second set of conductive lines, and wherein at least one third conductive line of the second set of conductive lines is disposed between the second conductive line of the second set of conductive lines and the first conductive line of the second set of conductive lines in the second conductor layer.

10. The inductive device of claim 1, wherein the second conductor layer further comprises a set of jumpers, wherein each jumper of the set of jumpers connects to two non-adjacent external connectors of the second set of external connectors.

11. A device comprising:
an inductive device comprising:
a first packaged device comprising:
a first body;
a first conductor layer at least partially enclosed within the first body and comprising a first set of conductive lines arranged substantially parallel to one another; and
a first set of external connectors coupled to the first set of conductive lines, wherein ends of the first set of external connectors are exposed on a face of the first body through openings in the first body; and
a second packaged device comprising:
a second body;
a second conductor layer at least partially enclosed within the second body and comprising a second set of conductive lines arranged substantially parallel to one another and at an angle relative to the first set of conductive lines; and
a second set of external connectors coupled to the second conductor layer, wherein ends of the second set of external connectors are exposed on a face of the second body through openings in the second body; and
wherein the first set of external connectors are coupled to the second set of external connectors to electrically connect the first set of conductive lines to the second set of conductive lines to define a coil having multiple turns, each turn including a conductive line of the first set of conductive lines and a conductive line of the second set of conductive lines.

12. The device of claim 11, wherein the first body comprises:
a second face opposite the face of the first body exposing the first set of external electrical connectors; and
one or more sides between the face and the second face, and wherein ends of the first set of conductive lines extend past the one or more sides to form a set of external leads.

13. The device of claim 12, further comprising a circuit board comprising a plurality of circuit components, wherein at least two external leads of the set of external leads are electrically connected to one or more circuit components of the plurality of circuit components.

14. The device of claim 13, wherein at least one external lead of the set of external leads is physically connected to the circuit board and is not electrically connected to the plurality of circuit components.

15. The device of claim 11, wherein each conductive line of the first set of conductive lines and each conductive line of the second set of conductive lines has a thickness of between 50 and 150 micrometers.

16. A method comprising:
providing a first packaged device comprising:
a first body;
a first conductor layer at least partially enclosed within the first body and comprising a first set of conductive lines extending along a first direction and offset from one another in a second direction; and
a first set of external connectors electrically connected to the first conductor layer and extending along a third direction, through openings in the first body, to a face of the first body;
providing a second packaged device comprising:
a second body;
a second conductor layer at least partially enclosed within the second body and comprising a second set of conductive lines offset from one another in the second direction and extending along a fourth direction that is angularly offset from the first direction; and
a second set of external connectors electrically connected to the second conductor layer and extending along the third direction, through openings in the second body, to a face of the second body; and
coupling the first set of external connectors and the second set of external connectors to electrically connect the first set of conductive lines to the second set of conductive lines to define a coil having multiple turns, each turn including a conductive line of the first set of conductive lines and a conductive line of the second set of conductive lines.

17. The method of claim 16, wherein ends of the first set of conductive lines extend along the first direction past one or more sides of the first body to define a set of external leads, and further comprising electrically connecting the coil to one or more circuit components of a circuit board via at least two external leads of the set of external leads.

18. The method of claim 17, further comprising physically connecting at least one external lead of the set of external leads to the circuit board without forming an electrical connection between the at least one external lead and any circuit component of the circuit board.

19. The method of claim 16, wherein providing the first packaged device comprises:
at least partially encapsulating the first conductor layer and the first set of external connectors in a mold compound; and
curing the mold compound to form the first body.

20. The method of claim 19, wherein the first conductor layer comprises a portion of a lead frame structure, and further comprising separating the first conductor layer from the lead frame structure.

21. The method of claim 16, wherein providing the second packaged device comprises:
at least partially encapsulating the second conductor layer and the second set of external connectors in a mold compound; and
curing the mold compound to form the second body.

22. The method of claim 21, wherein the second conductor layer comprises a portion of a lead frame structure, and further comprising separating the second conductor layer from the lead frame structure.

23. The method of claim 16, wherein a first external connector coupled to a first conductive line of the first set of conductive lines is coupled to a first external connector that is coupled to a first conductive line of the second set of conductive lines, and a second external connector coupled to the first conductive line of the first set of conductive lines is coupled to a second external connector that is coupled to a second conductive line of the second set of conductive lines, and wherein the second conductive line of the second set of conductive lines is adjacent to the first conductive line of the second set of conductive lines in the second conductor layer.

24. The method of claim 16, wherein a first external connector coupled to a first conductive line of the first set of conductive lines is coupled to a first external connector that is coupled to a first conductive line of the second set of conductive lines, and a second external connector coupled to the first conductive line of the first set of conductive lines is coupled to a second external connector that is coupled to a second conductive line of the second set of conductive lines, and wherein at least one third conductive line of the second set of conductive lines is disposed between the second conductive line of the second set of conductive lines and the first conductive line of the second set of conductive lines in the second conductor layer.

25. The method of claim 16, wherein the second conductor layer further comprises a set of jumpers, wherein each jumper of the set of jumpers connects to two non-adjacent external connectors of the second set of external connectors.

26. A transformer device comprising:
a first packaged device comprising:
a first body;
a first conductor layer at least partially enclosed within the first body and comprising a first set of conductive lines arranged substantially parallel to one another; and
a first set of external connectors coupled to the first set of conductive lines, wherein ends of the first set of external connectors are exposed on a face of the first body through openings in the first body; and
a second packaged device comprising:
a second body;
a second conductor layer at least partially enclosed within the second body and comprising a second set of conductive lines and a set of jumpers, wherein the second set of conductive lines are arranged substantially parallel to one another and at an angle relative to the first set of conductive lines; and
a second set of external connectors coupled to the second conductor layer, wherein ends of the second set of external connectors are exposed on a face of the second body through openings in the second body; and
wherein the first set of external connectors are coupled to the second set of external connectors to electrically connect the first set of conductive lines to the second set of conductive lines to define a first coil having multiple turns and a second coil having multiple turns.

27. The transformer device of claim 26, wherein the first body comprises:
a second face opposite the face of the first body exposing the first set of external electrical connectors; and
one or more sides between the face and the second face, and wherein ends of the first set of conductive lines extend past the one or more sides to form a set of external leads.

28. The transformer device of claim 26, wherein the first body, the second body, or both, comprise mold compound including a magnetic filler material.

29. The transformer device of claim 26, wherein each conductive line of the first set of conductive lines and each conductive line of the second set of conductive lines has a thickness of between 50 and 150 micrometers.

30. The transformer device of claim 26, wherein each jumper of the set of jumpers connects to two non-adjacent external connectors of the second set of external connectors.
